(19) United States
(12) Patent Application Publication
(10) Pub. No.: US 2006/0022319 A1
(43) Pub. Date: Feb. 2, 2006

(54) Airtight package, piezoelectric device, and piezoelectric oscillator

(75) Inventors: Juichiro Matsuzawa, Minowa-Machi (JP); Kazuhiko Shimodaira, Minowa-Machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/188,766

(22) Filed: Jul. 26, 2005

(30) Foreign Application Priority Data
Jul. 29, 2004 (JP) 2004-221415
May 13, 2005 (JP) 2005-140731

(51) Int. Cl. H01L 31/0203

(52) U.S. Cl. 257/678

(57) ABSTRACT

An airtight package has an insulating base having an opening approximately in the center and a recessed portion penetrating the insulating base in a thickness direction on a circumferential surface of the insulating base. The airtight package also has a lid sealed against the insulating base so as to block the opening. The lid is bonded to the insulating base in a manner that an edge of the lid overlaps the recessed portion exposed on an opening-side surface of the insulating base.

### BACKGROUND

The exemplary embodiments relate to an airtight package housing an element such as a quartz resonating piece and to a piezoelectric device and a piezoelectric oscillator using the airtight package.

With a related art airtight package, such as one depicted in Japanese Unexamined Patent Publication No. 2002-124832 (FIG. 2(b), page 3) shown in FIG. 11, a lid 101 is bonded with a bonding material to an opening surface 102 having a ceramic base 100 containing an opening 108 in a shape of an approximate rectangular solid as an example of an insulating base. The lid 101 is bonded so that an edge 106 of the lid 101 is in a region between the opening 108 and a bottom part 107 of each of recessed portions 103a, 103b, 104a, and 104b provided on circumferential surfaces of the ceramic base 100. In other words, the lid 101 is bonded in such a manner that the edge 106 of the lid 101 does not overlap each of the recessed portions 103a, 103b, 104a, and 104b.

However, with the airtight package of the referenced related art, the edge 106 of the lid 101 is in a bonding region, where the lid 101 is bonded to the ceramic base 100, between the opening 108 and the bottom part 107 of each of the recessed portions 103a, 103b, 104a, and 104b, and, therefore, if the lid 101 moves in any direction when bonding, an edge of the lid 101 opposite from this moving direction moves towards the center of the ceramic base 100, and an area where the ceramic base 100 is bonded to the lid 101 shrinks by a portion that the lid 101 has moved. If the bonded area shrinks, a bonding strength weakens at the shrunk portion. Accordingly, the bonded lid may peel off, and airtightness cannot be maintained when thermal fluctuation or shock is applied.

### SUMMARY

The exemplary embodiments provide an airtight package in which the lid can be bonded by a simple positioning of the lid without reducing the bonded area when bonded to the insulating base. In other words, the exemplary embodiments to provide an airtight package in which the bonding strength does not decrease even when there is some movement in the positions of the lid and in which the bonded lid does not easily peel off even when thermal fluctuation or shock is applied.

According to an aspect of the exemplary embodiments, an airtight package includes: an insulating base having a circumferential surface, an opening approximately in a center of the insulating base, and a recessed portion penetrating the insulating base in a thickness direction on the circumferential surface of the insulating base; and a lid having an edge, the lid sealed against the insulating base so as to block the opening. The lid is bonded to the insulating base so that the edge of the lid overlaps the recessed portion exposed on an opening-side surface of the insulating base.

The airtight package of the above aspect has the edge of the lid within the recessed portion exposed on the opening-side surface of the insulating base, and the edge of the lid overlapping the recessed portion. This structure ensures the edge of the lid does not reach the bonding portion even if the lid moves somewhat. Since the bonding can be conducted without reducing the bonded area, it is possible to provide an airtight package in which the bonding strength does not decrease and in which the bonded lid does not peel off even when thermal fluctuation or shock is applied.

Further, a width between opposing edges of the lid may be larger than a width between one circumferential surface of the insulating base, on a side bonded to the edge of the lid, and a bottom part of the recessed portion on another circumferential surface. The width between opposing edges of the lid may not be larger than a width between opposing circumferential surfaces of the insulating base, on the side bonded to the edge of the lid.

In this case, with a simple positioning, in which the width between the opposing circumferential surfaces of the insulating is set as a referential width, the edge of the lid always overlaps each of the recessed portions. More specifically, if one edge of the lid is positioned so as to completely overlap the corresponding circumferential surface of the insulating base, the other (opposite) edge of the same lid is positioned closer to its corresponding circumferential surface of the insulating base than to the bottom part of the recessed portion provided on this corresponding circumferential surface of the insulating base. In other words, the opposite edge overlaps this recessed portion. When the lid moves from this position, in a manner that the edge of the completely-overlapping lid moves gradually away from the corresponding circumferential surface of the insulating base, the opposite edge of the lid moves towards its corresponding circumferential surface of the insulating base so as to completely overlap this circumferential surface. Thus, all the edges of the lid always overlap the recessed portions, and, further, the bonding portions of the lid and the insulating base, that are closer to the center than the recessed portions are, always fit together. Accordingly, the lid and the insulating base can always be bonded without reducing the bonded area, and, therefore, it is possible to provide the airtight package in which the bonding strength does not decrease and in which the bonded lid does not peel off even when thermal fluctuation or shock is applied.

The bonding of the lid to the insulating base may be carried out at a bonding portion provided at least in a region that passes the edge of the opening and at least at one bottom or inside part of the recessed portion of the insulating base. The bonding portion is formed between hypothetical lines approximately parallel to the edges of the opening.

In this case, because the edge of the lid is within the recessed portion exposed on the opening-side surface of the insulating base, the edge of the lid overlaps the bonding portion even when the lid moves somewhat. That is to say that the edge of the lid never gets closer to the center of the insulating base than does the bottom part of the recessed portion. Further, the bonding portion is formed at least in the region that passes the edge of the opening and the bottom part of the insulating base, between the hypothetical lines approximately parallel to the edges of the opening. Consequently, because the edge of the lid does not reach the bonding portion, the bonded area where the lid is bonded to the insulating base may not shrink. The bonding strength is proportional to the bonded area, in that the larger the bonded area, the larger the bonding strength. Therefore, it is possible to provide the airtight package having sufficient bonding strength in which the bonding strength does not decrease and in which the bonded lid does not peel off even when thermal fluctuation or shock is applied.

The bonding of the lid to the insulating base may be carried out at a bonding portion provided in an entire region that passes the edge of the opening and at least one bottom or inside part of the recessed portion of the insulating base. The bonding portion may be formed between hypothetical lines approximately parallel to the edges of the opening.

In this case, because the edge of the lid does not reach the bonding portion, the lid can be bonded to the insulating base in the entire region that passes the edge of the opening and at least one bottom or inside part of the recessed portion of the insulating base, between the hypothetical lines approximately parallel to the edges of the opening. Accordingly, the bonded area can be larger, and the bonding can be sufficiently strong. Accordingly, it is possible to provide the airtight package in which the bonded lid does not peel off even when thermal fluctuation or shock is applied.

Furthermore, the bonding portion spread may be on an inner wall of the recessed portion.

In this case, because the bonding portion on the inner wall of the recessed portion can be formed to have a length in the thickness direction of the insulating base, there may be more strength against a force trying to peel the lid off the insulating base in the thickness direction. Further, because the bonding area can be larger, the bonding strength can also be larger. Accordingly, it is possible to provide the airtight package in which the bonded lid does not peel off even when thermal fluctuation or shock is applied.

According to another exemplary embodiment, a piezoelectric device includes: an insulating base having a circumferential surface, an opening approximately in a center of the insulating base, and a recessed portion penetrating the insulating base in a thickness direction on the circumferential surface of the insulating base; a lid having an edge, the lid sealed against the insulating base so as to block the opening; and a piezoelectric resonating piece mounted inside the opening, the lid being bonded to the insulating base so that the edge of the lid overlaps the recessed portion exposed on an opening-side surface of the insulating base.

In this case, because the piezoelectric device has the edge of the lid within the recessed portion exposed on the opening-side surface of the insulating base, and because the edge of the lid overlaps the recessed portion, the edge of the lid may not reach the bonding portion even when the lid moves somewhat. Accordingly, because the bonding can be conducted without reducing the bonded area, it is possible to prevent the bonded lid from peeling off when thermal fluctuation or shock is applied. Consequently, because the piezoelectric device having the piezoelectric resonating piece connected inside the opening of the insulating base can have reliable airtightness, it is possible to prevent or discourage degradation in characteristics of the piezoelectric resonating piece due to decreased airtightness and to further improve reliability of the piezoelectric device.

Further, a width between opposing edges of the lid may be larger than a width between one circumferential surface of the insulating base, on a side bonded to the edge of the lid, and a bottom part of the recessed portion on a circumferential surface opposite the one circumferential surface. The width between opposing edges of the lid may not be larger than a width between opposing circumferential surfaces of the insulating base on the side bonded to the edge of the lid.

In this case, similarly to the airtight package, because the insulating base and the lid can be bonded without reducing the bonded area by the simple positioning of the lid, it is possible to provide the piezoelectric device in which the bonding strength does not decrease and in which the bonded lid does not peel off even when thermal fluctuation or shock is applied.

The lid may be bonded to the insulating base at a bonding portion provided at least in a region which passes the edge of the opening and at least one bottom or inside part of the recessed portion of the insulating base. The bonding portion being formed between hypothetical lines approximately parallel to the edges of the opening.

In this case, because the edge of the lid is within the recessed portions exposed on the opening-side surface of the insulating base, the edge of the lid overlaps the bonding portion even when the lid moves somewhat. That is, the edge of the lid never gets closer to the center of the insulating base than does the bottom part of the recessed portion. Further, the bonding portion is formed at least in the region that passes the edges of the opening and the bottom part of the recessed portion of the insulating base, between the hypothetical lines approximately parallel to the edges of the opening. Accordingly, because the edge of the lid does not reach the bonding portion, the bonded area where the lid is bonded to the insulating base may not shrink. The bonding strength is proportional to the bonded area, in that the larger the bonded area, the larger the bonding strength. Therefore, it is possible to provide the piezoelectric device having sufficient bonding strength in which the bonding strength does not decrease and in which the bonded lid does not peel off even when thermal fluctuation or shock is applied.

The lid may be bonded to the insulating base at a bonding portion provided in an entire region which passes the edge of the opening and at least one bottom or inside part of the recessed portion of the insulating base. The bonding portion being formed between hypothetical lines approximately parallel to the edges of the opening.

In this case, because the edge of the lid does not reach the bonding portion, the lid can be bonded to the insulating base in the entire region that passes the edge of the opening and at least one bottom part of the recessed portion of the insulating base, between the hypothetical lines approximately parallel to the edges of the opening. Accordingly, the bonded area can be larger, and the bonding can be sufficiently strong. Accordingly, it is possible to provide the piezoelectric device in which the bonded lid does not peel off even when thermal fluctuation or shock is applied.

The bonding portion spread may be on an inner wall of the recessed portion.

In this case, because the bonding portion that on the inner wall of the recessed portion can be formed to have a length in the thickness direction of the insulating base, there may be more strength against the force trying to peel the lid off the insulating base in the thickness direction. Further, because the bonding area can be larger, the bonding strength can also be larger. Accordingly, it is possible to provide the piezoelectric device in which the bonded lid does not peel off even when thermal fluctuation or shock is applied.

According to yet another exemplary embodiment, a piezoelectric oscillator includes: an insulating base having a circumferential surface, an opening approximately in a center of the insulating base, and a recessed portion penetrating the insulating base in a thickness direction on the circumferential surface of the insulating base; a lid having an edge, the lid sealed against the insulating base so as to block the opening, a piezoelectric resonating piece mounted inside the opening; and a circuit element to at least oscillate the piezoelectric resonating piece, the circuit element being mounted inside the opening, the lid being bonded to the insulating base so that the edge of the lid overlaps the recessed portion exposed on an opening-side surface of the insulating base.

In this case, because the edge of the lid is within the recessed portion exposed on the opening-side surface of the insulating base and because the edge of the lid is overlapping the recessed portion, the edge of the lid does not reach the bonding portion even when the lid moves somewhat. Accordingly, because the bonding can be conducted without reducing the bonded area, it is possible to prevent the bonded lid from peeling off when thermal fluctuation or shock is applied. Accordingly, because the piezoelectric oscillator having the piezoelectric resonating piece and the circuit element connected inside the opening of the insulating base can have reliable airtightness, it is possible to prevent degradation in characteristics of the piezoelectric resonating piece due to decreased airtightness and to further improve reliability of the piezoelectric oscillator.

Further, with the piezoelectric oscillator, a width between opposing edges of the lid may be larger than a width between one circumferential surface of the insulating base on a side bonded to the edge of the lid and a bottom part of the recessed portion on a circumferential surface opposite the one circumferential surface. The width between the opposing edge of the lid may not be larger than a width between opposing circumferential surfaces of the insulating base on the side bonded to the edge of the lid.

In this case, similarly to the airtight package, because the insulating base and the lid can be bonded without reducing the bonded area by the simple positioning of the lid, it is possible to provide the piezoelectric oscillator in which the bonding strength does not decrease and in which the bonded lid does not peel off even when thermal fluctuation or shock is applied.

The lid may be bonded to the insulating base at a bonding portion provided at least in a region which passes the edge of the opening and at least one bottom or inside part of the recessed portion of the insulating base. The bonding portion may be formed between hypothetical lines approximately parallel to the edges of the opening.

In this case, because the edge of the lid is within the recessed portion exposed on the opening-side surface of the insulating base, the edge of the lid overlaps the bonding portion even when the lid moves somewhat. That is, the edge of the lid never gets closer to the center of the insulating base than does the bottom part of the recessed portion. Further, the bonding portion is formed at least in the region that passes the edge of the opening and the bottom part of the recessed portion of the insulating base, between the hypothetical lines approximately parallel to the edges of the opening. Accordingly, because the edge of the lid does not reach the bonding portion, the bonded area where the lid is bonded to the insulating base may not shrink. The bonding strength is proportional to the bonded area, in that the larger the bonded area, the larger the bonding strength. Therefore, it is possible to provide the piezoelectric oscillator having sufficient bonding strength in which the bonding strength does not decrease and in which the bonded lid does not peel off even when thermal fluctuation or shock is applied.

The lid may be bonded to the insulating base at a bonding portion provided in an entire region which passes the edge of the opening and at least one bottom part of the recessed portion of the insulating base. The bonding portion is formed between hypothetical lines approximately parallel to the edges of the opening.

In this case, because the edge of the lid does not reach the bonding portion, the lid can be bonded to the insulating base in the entire region that passes the edge of the opening and the bottom of the insulating base, between the hypothetical lines approximately parallel to the edges of the opening. Accordingly, the bonded area can be larger, and the bonding can be sufficiently strong. Accordingly, it is possible to provide the piezoelectric oscillator in which the bonded lid does not peel off even when thermal fluctuation or shock is applied.

The bonding portion spread may be on an inner wall of the recessed portion.

In this case, because the bonding portion on the inner wall of the recessed portion can be formed to have a length in the thickness direction of the insulating base, there may be more strength against the force trying to peel the lid off the insulating base in the thickness direction. Further, because the bonding area can be larger, the bonding strength can also be larger. Accordingly, it is possible to provide the piezoelectric oscillator in which the bonded lid does not peel off even when thermal fluctuation or shock is applied.

### BRIEF DESCRIPTION OF THE DRAWINGS

The exemplary embodiments will be described with reference to the accompanying drawings, wherein like numbers refer to like elements and wherein:

FIG. 1 is a schematic, perspective view of an airtight package of a first exemplary embodiment, with a lid being partially cut away;

FIG. 2 is a plan view of the airtight package, showing a bonding material in a planar shape of the first exemplary embodiment;

FIG. 3 is a plan view of the airtight package, showing the bonding material in another planar of the first exemplary embodiment;

FIG. 4 is a cross-sectional schematic of FIG. 3 taken on an A-A′ line, showing a shape of the bonding material inside a recessed portion;

FIG. 5 is a cross-sectional schematic of FIG. 3 taken on the A-A′ line, showing another shape of the bonding material inside the recessed portion;

FIGS. 6A and 6B are front and left-side elevational views (cross-sectional views) of a bonding condition inside the recessed portion of the first exemplary embodiment;

FIG. 7 is a schematic plan view of a quartz resonator of a second exemplary embodiment, with the lid being partially cut away;

FIG. 8 is a schematic cross-sectional front view of the quartz resonator of the second exemplary embodiment;

FIG. 9 is a schematic plan view of a quartz oscillator of a third exemplary embodiment, with the lid being partially cut away;

FIG. 10 is a schematic, cross-sectional front view of the quartz oscillator of the third exemplary embodiment; and

FIG. 11 is a schematic, perspective view of a related art airtight package, with the lid being partially cut away.

### DETAILED DESCRIPTION OF EMBODIMENTS

Exemplary embodiments will now be described with reference to the drawings. It is to be noted that the exemplary embodiments are not limited to the following described embodiments.

### First Exemplary Embodiment

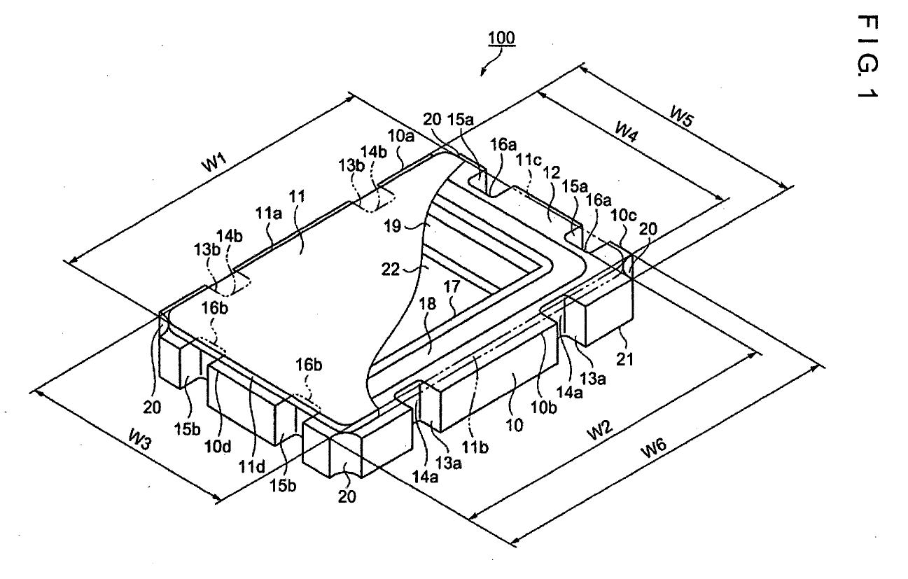

An airtight package of a first exemplary embodiment will be described with reference to FIG. 1. FIG. 1 is a schematic, perspective diagram of the airtight package of the first exemplary embodiment with part of the lid being omitted.

As shown in FIG. 1, an airtight package 100 is composed of an insulating base 10 made of ceramic or the like, a lid 11 that seals an opening 17 of the insulating base 10, and a bonding material 18 as a bonding portion, the lid 11 being bonded to the insulating base 10.

The insulating base 10 is in a shape of an approximate rectangular solid, and on circumferential surfaces 10a, 10b, 10c, and 10d thereof, there are formed two pairs each of recessed portions 13a, 13b, 15a, and 15b and an incised portion 20 on each of four corners of the insulating base 10. On an inner surface of each of the recessed portions 13a, 13b, 15a, and 15b, a ground electrode or a conductive electrode (not shown) is formed. A depth of the recessed portions 13a, 13b, 15a, and 15b reaches up to bottom parts 14a, 14b, 16a, and 16b on a center side of the insulating base 10 (hereinafter referred to as the “bottom parts”). Further, the recessed portions 13a, 13b, 15a, and 15b are formed successively in (or so as to penetrate) the insulating base 10, from a surface (hereinafter referred to as the “upper surface”) 12 having the opening 17 in the insulating base 10 up to a back surface 21. Therefore, on the upper surface 12 and the back surface 21, cross-sectional configurations of the recessed portions 13a, 13b, 15a, and 15b are exposed. Additionally, the recessed portions 13a, 13b, 15a, and 15b may be called castellations.

The insulating base 10 includes the opening 17 approximately in the center thereof. The opening 17 has a recessing configuration having a predetermined depth. On part of a bottom 22 of the opening 17, there is formed a supporting portion 19 that supports electronic elements such as the piezoelectric resonating piece to be housed in the opening 17. Further, the bonding material 18, that bonds the lid 11 to the insulating base 10 and has a predetermined width, is provided on an inside of the upper surface 12 of the insulating base 10 and between the edge of the opening 17 to the bottom parts 14a, 14b, 16a, and 16b of the recessed portions 13a, 13b, 15a, and 15b. Further, the bonding material 18 may be a solder material such as gold (Au)—tin (Sn) alloy, for example.

The lid 11 is a thin sheet made of Kovar, stainless steel, or glass, for example, and is used to airtightly seal the opening 17 of the insulating base 10. Edges 11a, 11b, 11 c, and 11d of the lid 11 are within the circumferential surfaces 10a, 10b, 10c, and 10d of the insulating base 10 and are bonded in a matter that they partially overlap each of the recessed portions 13a, 13b, 15a, and 15b exposed on the upper surface 12 of the insulating base 10. In other words, the lid 11 is positioned so as to partially cover each of the exposed recessed portions 13a, 13b, 15a, and 15b and is bonded to the insulating base 10 via the bonding material 18. This bonding is carried out by a fusion technique in which a heating furnace or the like is used to melt the bonding material 18 at a temperature as high as 280° C., for example.

According to the airtight package 100 of the first exemplary embodiment, the edges 11a, 11b, 11c, and 11d of the lid 11 are positioned within the recessed portions 13a, 13b, 15a, and 15b exposed on the upper surface 12 of the insulating base 10. Accordingly, even when the lid 11 moves somewhat from its position, the edges 11a, 11b, 11c, and 11d of the lid 11 overlap the recessed portions 13a, 13b, 15a, and 15b and do not reach the portion bonded to the bonding material 18. That is, even when the positioning of the lid 11 is such that allows some positional movement, the bonding can be done without reducing the bonded area. Therefore, it is possible to provide the airtight package 100 in which the bonding strength does not decrease and which the bonded lid 11 does not peel off even when thermal fluctuation or shock is applied.

Additionally, outline sizes of the lid 11 are set within the ranges as hereafter explained. For example, in FIG. 1, a width W3 between the edge 11a and the opposing edge 11b of the lid 11 in an anteroposterior direction (or diagonally right down in the drawing) is set to be larger than a width W4 between the circumferential surface 10a at the posterior side of the insulating base 10 and the bottom part 14a of the recessed portion 13a provided on the opposing circumferential surface 10b. The width W3 is set to be smaller than a width W5 between the circumferential surface 10a at the posterior side of the insulating base 10 and the circumferential surface 10b at the anterior side of the insulating base 10. Similarly, a width W1 between the edge 11c and the opposing edge 1d of the lid 11 in an horizontal direction (diagonally right up in the drawing) is set to be larger than a width W2 between the circumferential surface 10d at the left side, as shown, of the insulating base 10 and the bottom part 16a of the recessed portion 15a provided on the circumferential surface 10c opposite from this circumferential surface 10d. The width W1 is set to be smaller than a width W6 between the circumferential surface 10d at the left side of the insulating base 10 and the circumferential surface 10c at the right side of the insulating base 10.

By thus setting the outline sizes of the lid 11, the edges 11a, 11b, 11c, and 11d of the lid 11, within the outline widths W5 and W6, can be formed within the recessed portions 13a, 13b, 15a, and 15b exposed on the upper surface 12 of the insulating base 10. This will be further explained. The position of the lid 11 is determined by setting the outline widths W5 and W6 of the insulating base 10 as the outermost positions, thereby a movable range of the lid 11 is determined. In this case, if the edge 11a of the lid 11 moves from a position of the circumferential surface 10a of the insulating base 10 to a position of the bottom part 14b of the recessed portion 13b, for example, the opposing edge 11b of the lid 11 moves from a position of the bottom part 14a of the recessed portion 13a to a position of the edge 10b of the insulating base 10. In other words, by setting the outline widths W5 and W6 as the referential widths and by positioning the lid 11 within the ranges of the widths W5 and W6, the edges 11a, 11b, 11c, and lid of the lid 11 will always be positioned within the recessed portions 13a, 13b, 15a, and 15b exposed on the upper surface 12 of the insulating base 10. Accordingly, because the edges 11a, 11b, 11c, and 11d of the lid 11 do not overlap the bonding material 18, and because the lid 11 can be bonded to the insulating base 10 without shrinking the bonded area, it is possible to provide the airtight package 100 with a bonding strength that is not reduced, decreased or minimized with a bonded lid that does not peel off, even when thermal fluctuation or shock is applied.

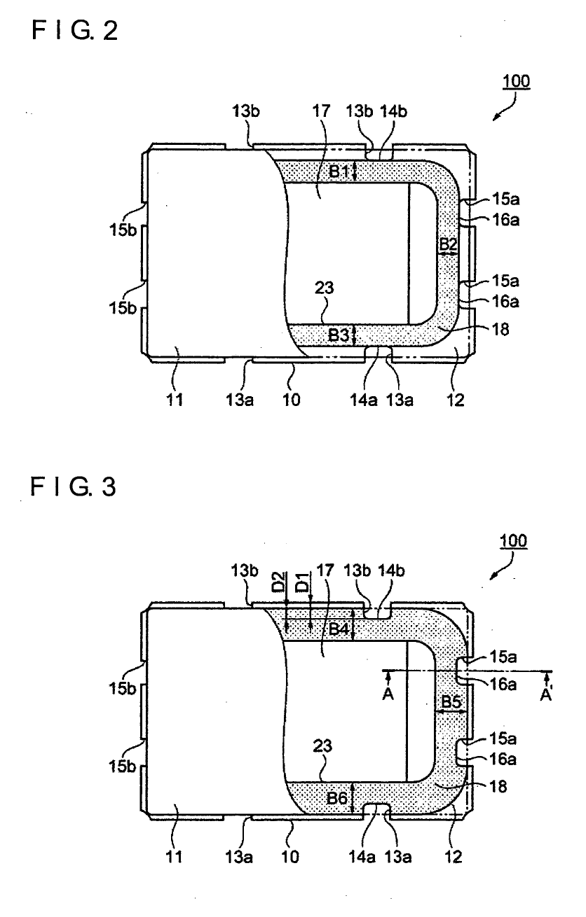

Now, another shape of the bonding material 18 will be described with reference to the drawings. FIGS. 2 and 3 are plan schematics of the airtight package, showing a planar shape of the bonding material 18.

As shown in FIG. 2, the bonding material 18 is formed on the upper surface 12 of the insulating base 10 in the entire region between the edge 23 of the opening 17 and the bottom parts 14a, 14b, 16a, and 16b of the recessed portions 13a, 13b, 15a, and 15b, having widths B1, B2, and B3, for example. In this case, an edge of the bonding material 18 on the recessed portion side is formed so as to almost parallel with the edge 23 of the opening 17. Additionally, the edge of the bonding material 18 on the recessed portion side may be either straight or curved.

When using the bonding material 18 having such a shape, the edge of the lid 11 does not reach the bonding portion, and, thus, the lid 11 can be bonded to the insulating base 10 in the entire region between the edge 23 of the opening 17 and the bottom parts 14a, 14b, 16a, and 16b of the recessed portions 13a, 13b, 15a, and 15b. Accordingly, the bonded area can be larger, and the bonding can be sufficiently strong. Accordingly, it is possible to provide the airtight package 100 in which the bonded lid 11 does not peel off even when thermal fluctuation or shock is applied.

In the descriptions above, a composition having the same depth of the bottom parts 14a, 14b, 16a, and 16b of the recessed portions 13a, 13b, 15a, and 15b was used as an example. Accordingly, the bonding material 18 has a composition so as to pass all the bottom parts 14a, 14b, 16a, and 16b. However, other compositions are possible. If the depths of the recessed portions 13a, 13b, 15a, and 15b differ, the bonding material 18 may only be provided in a region between the edge 23 of the opening 17 and the edge which passes any of the bottom parts 14a, 14b, 16a, and 16b and which is approximately parallel to the edge 23 of the opening 17. Further, if the bonding material 18 is provided so as to pass the bottom parts at an outermost part of the insulating base 10 and be approximately parallel to the edge 23 of the opening 17, the bonded area of the bonding material 18 becomes larger and is therefore more desirable.

In addition, as shown in FIG. 3, the bonding material 18 may have a composition in which the edge of the bonding material 18 is in a region overlapping the recessed portions 13a, 13b, 15a, and 15b. The bonding material 18 is provided between the edge 23 of the opening 17 and the other edge that overlaps the recessed portions 13a, 13b, 15a, and 15b, having widths B4, B5, and B6, for example. In this case, if the edge on the recessed-portion side is provided near the circumferential surface of the insulating base 10, the bonding material 18 that melts at the time of bonding may flow over to the circumferential surface of the insulating base 10, creating a raised configuration on the circumferential surface of the insulating base 10 and irregularly shaping the circumferential surface. In order to avoid the occurrence of irregularly shaping the circumferential surface, it is desirable that the edge on the recessed-portion side of the bonding material 18 be set at a depth D2, which is approximately two thirds of a depth D1, up to the edge 23 of the opening and the bottom parts 14a, 14b, 16a, and 16b of the recessed portions 13a, 13b, 15a, and 15b.

With the bonding material 18 having such a shape as shown in FIG. 3, even a larger bonding area can be obtained, and, therefore, the bonding can be sufficiently strong. Accordingly, it is possible to provide the airtight package 100 in which the bonded lid 11 does not peel off even when thermal fluctuation or shock is applied.

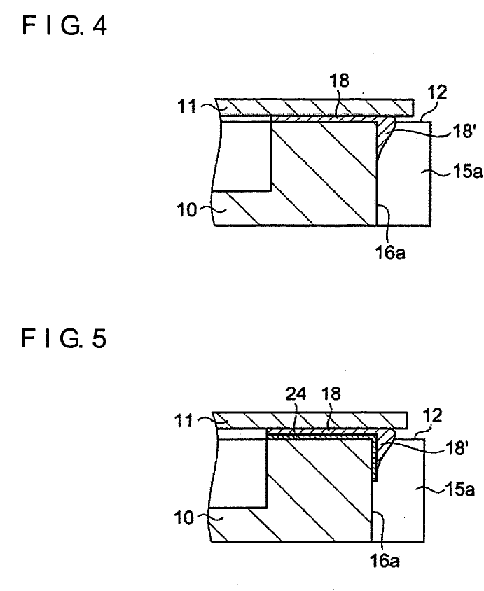

Further, as shown in FIG. 4, there may be a filet 18′ created when the bonding material 18 spreads over an inner wall, including the bottom part 16a of the recessed portion 15a, of the insulating base 10. The filet 18′ is formed when the bonding material 18, which is melt for bonding and provided between the insulating base 10 and the lid 11, flows towards the inner wall of the recessed portion 15a. To note, FIG. 4 is a cross-sectional diagram of FIG. 3 taken on a line A-A′.

In addition, as shown in FIG. 5, if the bonding material 18 has a poor bonding property against the insulating base 10 (when there is not enough bonding strength), a metal layer 24 is provided on the upper surface of the insulating base 10 and the inner wall of the recessed portion 15a. By using a gold (Au) layer, for example, for the metal layer 24, the metal layer 24 can give strength to the bonding between the bonding material 18 and the insulating base 10. To note, FIG. 5 is a cross-sectional diagram of FIG. 3 taken on the line A-A′.

By forming the filet 18′, the bonding material 18 as the bonding portion spreads on the insulating base 10 also in the thickness direction; therefore, there is more strength against force trying to peel the lid 11 off the insulating base 10 in the thickness direction. Also, because the bonding area becomes larger, the bonding strength becomes larger. Consequently, it is possible to provide the airtight package in which the bonded lid 11 does not easily peel off.

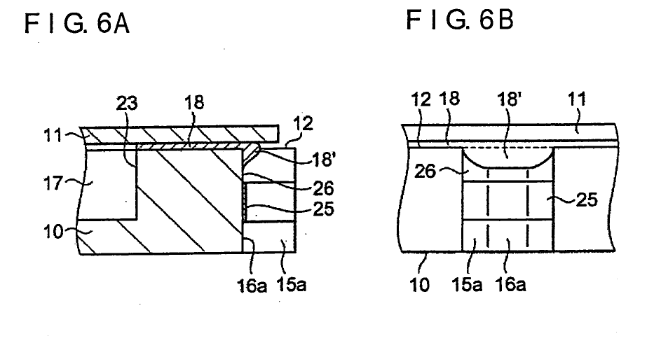

Now, a composition having an electrode 25 on the inner wall, including the bottom part 16a of the recessed portion 15a, will be described. FIGS. 6A and 6B show front and left-side elevational views (cross-sectional views), respectively, of and around the recessed portion 15a. As shown in FIGS. 6A and 6B, the bonding material 18 is formed on the upper surface 12 of the insulating base 10, and the lid 11 is bonded thereto so as to block the opening 17. Further, the bonding material 18 is provided in the aforementioned predetermined region outside the edge 23 of the opening 17. The electrode 25 is provided on the inner wall, including the bottom part 16a of the recessed portion 15a, formed on the insulating base 10. The electrode 25, is a connection electrode, or the like, connected to an element (not shown) that is to be housed in the opening 17. The electrode 25 is formed so as to include an insulating portion 26, such as the insulating base 10, between itself and the bonding material 18. The insulating portion 26 can prevent, for example, short circuit that happens when the flowing filet 18′ of the bonding material 18 comes in contact with the electrode 25. Additionally, an insulating film formed on a part of the surface of the electrode 25 may be used as the insulating portion 26.

Additionally, although the solder material such as gold (Au)—tin (Sn) alloy was used as the bonding material 18 to bond the lid 11 to the insulating base 10, other material may be used such as a seal ring of iron (Fe)—nickel (Ni) alloy die-cut into a frame shape. When using the seal ring, the seal ring is connected in advance to ground on the upper surface of the insulating base 10, and the seal ring and the lid 11 mounted on the surface of this seal ring are airtightly sealed by seam welding.

Further, although it was described that two pairs each of the recessed portions 13a, 13b, 15a, and 15b were formed on the circumferential surfaces 10a, 10b, 10c, and 10d of the insulating base 10, the recessed portions do not have to be formed on all the circumferential surfaces but may be formed on at least one of the circumferential surfaces. Moreover, there may be any number of recessed portions on one circumferential surface.

### Second Exemplary Embodiment

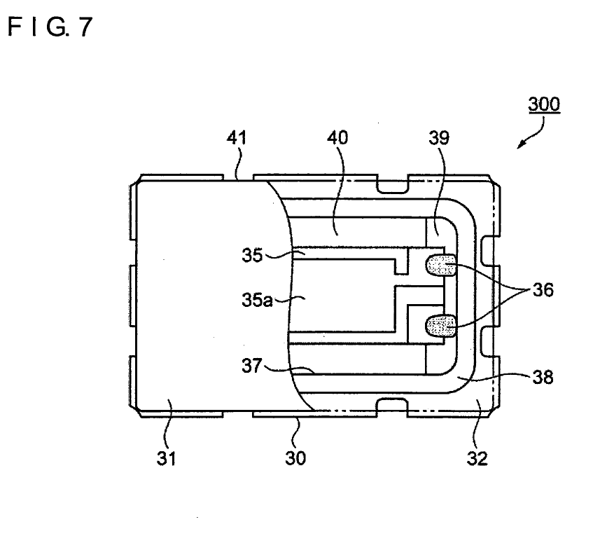

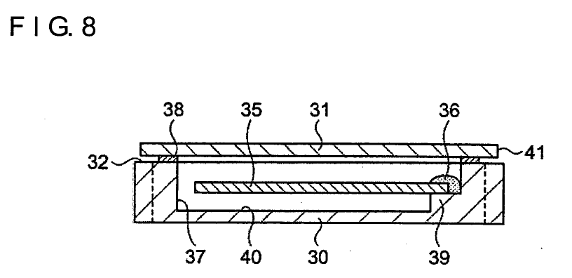

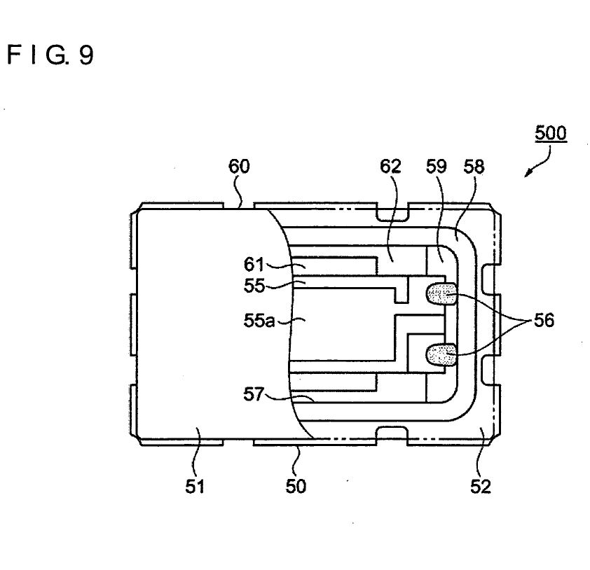

As one example of the piezoelectric device of the exemplary embodiments, the quartz resonator using the quartz resonating piece as the piezoelectric resonating piece will be described as the second exemplary embodiment. FIG. 7 is a schematic plan view of the quartz resonator of the second exemplary embodiment, with part of the lid being omitted. FIG. 8 is a schematic cross-sectional front view of the quartz resonator of the second exemplary embodiment.

As shown in FIGS. 7 and 8, a quartz resonator 300 is composed of an insulating base 30 made of ceramic or the like, a lid 31 that seals an opening 37 of the insulating base 30, a bonding material 38 used to bond the lid 31 to the insulating base 30, a quartz resonating piece 35, and a conductive adhesive 36 that connects the quartz resonating piece 35 with the insulating base 30.

Since the outer configurations and compositions of the insulating base 30 and the lid 31 and the bonding thereof in the second exemplary embodiment are the same as those in the first exemplary embodiment, descriptions thereof will be omitted.

At a bottom 40 of the opening 37 provided in the approximate center of the insulating base 30, a supporting portion 39 is provided. On the upper surface of the supporting portion 39, the quartz resonating piece 35, which is made of quartz or the like and has a resonating electrode 35a formed thereon, is connected and mounted using a connecting material such as the conductive adhesive 36. The conductive adhesive 36 contains pieces or particles of silver that are mixed in a resin base material as a filler and cured by heating or ultraviolet irradiation so as to also enable electrical connection.

The opening 37 of the insulating base 30 is airtightly sealed by the lid 31, which is bonded with the bonding material 38 formed on an upper surface 32 of the insulating base 30. Further, on the outer surface of the insulating base 30, a conductive wire section (not shown) led from the opening 37 is formed and bonded to a mounting board or the like.

According to the quartz resonator of the second exemplary embodiment, the quartz resonating piece 35 is housed in the opening 37 of the insulating base 30, and, by carrying out the sealing of the opening 37, as in the descriptions of the first exemplary embodiment, the lid 31 can be sealed without an edge 41 of the lid 31 overlapping the bonding material 38. Therefore, it is possible to provide the quartz resonator without reducing the area where the lid 31 is bonded to the insulating base 30 and without decreasing the bonding strength. In other words, it is possible to provide a more reliable and characteristically stable quartz resonator, in which the bonded lid does not peel off even when thermal fluctuation or shock is applied.

### Third Exemplary Embodiment

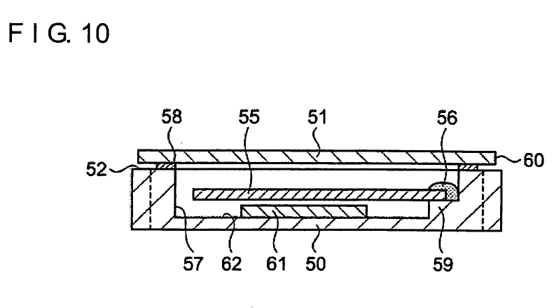

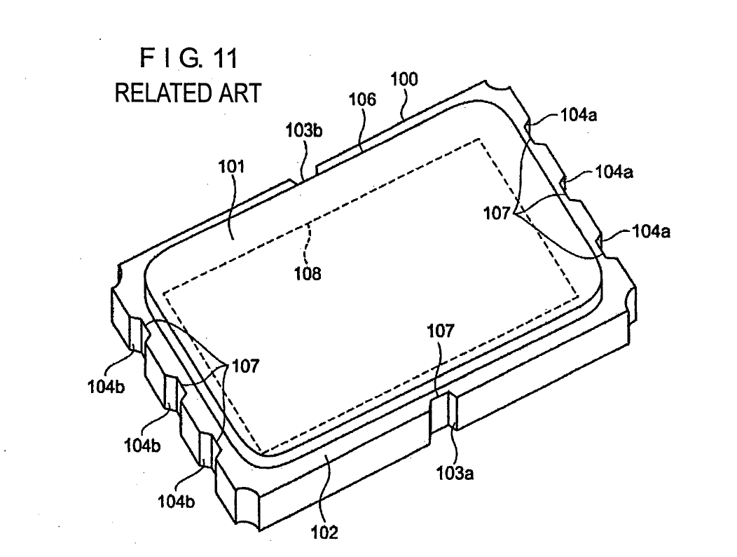

As one example of the piezoelectric oscillator of the exemplary embodiments, the quartz oscillator using the quartz resonating piece as a piezoelectric resonating piece will be described as the third exemplary embodiment. FIG. 9 is a schematic plan view of the quartz oscillator of the third exemplary embodiment, with part of the lid being removed. FIG. 10 is a schematic cross-sectional front view of the quartz oscillator of the third exemplary embodiment.

As shown in FIGS. 9 and 10, a quartz oscillator 500 is composed of an insulating base 50 made of ceramic or the like, a lid 51 that seals an opening 57 of the insulating base 50, a bonding material 58 used to bond the lid 51 to the insulating base 50, a quartz resonating piece 55, a conductive adhesive 56 that connects the a quartz resonating piece 55 with the insulating base 50, and a circuit element 61 having a function to at least oscillate the quartz resonating piece 55.

In the third exemplary embodiment, since the outer configurations and compositions of the insulating base 50 and the lid 51 and the bonding thereof are the same as those in the first exemplary embodiment, descriptions thereof will be omitted.

At a bottom 62 of the opening 57 provided in the approximate center of the insulating base 50, a supporting portion 59 is provided. On the upper surface of the supporting portion 59, the quartz resonating piece 55, which has a resonating electrode 55a formed thereon and is made of a thin sheet of quartz, is connected and mounted using a connecting material such as the conductive adhesive 56. This quartz resonating piece 55 is positioned so as to only have contact with the connection part. The conductive adhesive 56 contains pieces or particles of silver that are mixed in the resin base material as the filler and cured by heating or ultraviolet irradiation so as to also enable electrical connection. At a portion below the quartz resonating piece 55, on the bottom 62, of the opening 57 provided in the approximate center of the insulating base 50, the circuit element 61, which is connected by wire (not shown) with the quartz resonating piece 55 and has the function to at least oscillate the quartz resonating piece 55, is bonded with the conductive adhesive (not shown). In short, the circuit element 62 is also mounted inside the opening 57.

The opening 57 of the insulating base 50 is airtightly sealed by the lid 51, which is bonded with the bonding material 50 formed on the upper surface 52 of the insulating base 50. Further, on the outer surface of the insulating base 50, a conductive wire section (not shown) led from the opening 57 is formed and bonded to a mounting board or the like.

According to the quartz oscillator 500 of the third exemplary embodiment, the quartz resonating piece 55 is housed in the opening 57 of the insulating base 50. By carrying out the sealing of the opening 57, as in the descriptions of the first exemplary embodiment, the lid 51 can be sealed without an edge 60 of the lid 51 overlapping the bonding material 58. Therefore, it is possible to provide the quartz resonator 500 without reducing the area where the lid 51 is bonded to the insulating base 50 and without decreasing the bonding strength. In other words, it is possible to provide a more reliable and characteristically stable quartz resonator 500 in which the bonded lid 51 does not peel off even when thermal fluctuation or shock is applied.

The second and third exemplary embodiments were described by referring to the quartz resonating piece using quartz as an example of the piezoelectric resonating piece. However, the piezoelectric resonating piece may be of any material having a piezoelectric effect, such as lithium tantalate (LiTaO3), lead zirconate titanate (abbreviated to PZT), barium titanate (BaTiO3), or the like.

What is claimed is:

1. An airtight package, comprising:
an insulating base having a circumferential surface, an opening approximately in a center of the insulating base, and a recessed portion penetrating the insulating base in a thickness direction on the circumferential surface of the insulating base; and
a lid having an edge, the lid sealed against the insulating base so as to block the opening,
the lid being bonded to the insulating base so that the edge of the lid overlaps the recessed portion exposed on an opening-side surface of the insulating base.

2. The airtight package according to claim 1,
the circumferential surface having one side and an opposing side;
a width of the lid being larger than a width between the one side of the circumferential of the insulating base on a side bonded to the edge of the lid and a bottom part of the recessed portion on the opposing side of the circumferential surface, and
the width of the lid not being larger than a width between the one side and opposing side of the circumferential surface of the insulating base.

3. The airtight package according to claim 1, further comprising:
a bonding portion provided at least in a region which passes an edge of the opening and at least one bottom inside part of the recessed portion of the insulating base, the bonding portion being formed approximately parallel to the edge of the opening, the lid being bonded to the insulating base at the bonding portion.

4. The airtight package according to claim 1, further comprising:
a bonding portion provided in an entire region which passes an edge of the opening and at least one inside part of the recessed portion of the insulating base, the bonding portion being formed approximately parallel to the edge of the opening, the lid being bonded to the insulating base at the bonding portion.

5. The airtight package according to claim 1, further comprising:
a bonding portion on an inner wall of the recessed portion.

6. A piezoelectric device, comprising:
an insulating base having a circumferential surface, an opening-side surface, an opening approximately in a center of the insulating base, and a recessed portion penetrating the insulating base in a thickness direction the circumferential surface;
a lid having an edge, the lid sealed against the insulating base so as to block the opening; and
a piezoelectric resonating piece mounted inside the opening;
the lid being bonded to the insulating base in a manner that the edge of the lid overlaps the recessed portion exposed on the opening-side surface of the insulating base.

7. The piezoelectric device according to claim 6,
the circumferential surface having one side and an opposing side;
a width of the lid being larger than a width between the one side of the circumferential of the insulating base on a side bonded to the edge of the lid and a bottom part of the recessed portion on the opposing side of the circumferential surface, and
the width of the lid not being larger than a width between the one side and opposing side of the circumferential surface of the insulating base.

8. The piezoelectric device according to claim 6, further comprising:
a bonding portion provided at least in a region which passes an edge of the opening and at least one inside part of the recessed portion of the insulating base, the bonding portion being formed approximately parallel to the edge of the opening, the lid being bonded to the insulating base at the bonding portion.

9. The piezoelectric device according to claim 6,
a bonding portion provided in an entire region which passes an edge of the opening and at least one inside part of the recessed portion of the insulating base, the bonding portion being formed approximately parallel to the edge of the opening, the lid being bonded to the insulating base at the bonding portion.

10. The piezoelectric device according to claim 6, further comprising:
a bonding portion on an inner wall of the recessed portion.

11. A piezoelectric oscillator, comprising:
an insulating base having a circumferential opening, an opening-side surface, an opening approximately in a center of the insulating base, and a recessed portion penetrating the insulating base in a thickness direction on the circumferential surface;
a lid having an edge, the lid sealed against the insulating base so as to block the opening;
a piezoelectric resonating piece mounted inside the opening, and
a circuit element to at least oscillate the piezoelectric oscillating piece, the circuit element mounted inside the opening;
the lid being bonded to the insulating base in a manner that the edge of the lid overlaps the recessed portion exposed on the opening-side surface of the insulating base.

12. The piezoelectric oscillator according to claim 11,
the circumferential surface having one side and an opposing side;
a width of the lid being larger than a width between the one side of the circumferential of the insulating base on a side bonded to the edge of the lid and a bottom part of the recessed portion on the opposing side of the circumferential surface, and
the width of the lid not being larger than a width between the one side and opposing side of the circumferential surface of the insulating base.

13. The piezoelectric oscillator according to claim 11, further comprising:
a bonding portion provided at least in a region which passes an edge of the opening and at least one inside part of the recessed portion of the insulating base, the bonding portion being formed approximately parallel to the edge of the opening, the lid being bonded to the insulating base at the bonding portion.

14. The piezoelectric oscillator according to claim 11,
a bonding portion provided in an entire region which passes an edge of the opening and at least one inside part of the recessed portion of the insulating base, the bonding portion being formed approximately parallel to the edge of the opening, the lid being bonded to the insulating base at the bonding portion.

15. The piezoelectric oscillator according to claim 11, further comprising:
a bonding portion on an inner wall of the recessed portion.
